(19) United States
(12) Patent Application Publication
(10) Pub. No.: US 2024/0404848 A1
(43) Pub. Date: Dec. 5, 2024

(54) Mobile Cart for Commissioning Semiconductor Processing Tool

(71) Applicant: Applied Materials, Inc., Santa Clara, CA (US)

(72) Inventors: Sam KIM, San Jose, CA (US); Kon Tae PARK, Mountain House, CA (US); Yao-Hung YANG, Santa Clara, CA (US); Michael John PERRY, Los Gatos, CA (US); Michael LEVKOVITCH, Plano, TX (US); Ram Chandra PALSANIYA, Tracy, CA (US); Nitin KHURANA, Milpitas, CA (US); Derek MCQUARRIE, Tempe, AZ (US)

(21) Appl. No.: 18/239,783

(22) Filed: Aug. 30, 2023

Related U.S. Application Data
(60) Provisional application No. 63/469,658, filed on May 30, 2023.

(51) Int. Cl. H01L 21/67; H02J 7/00

(52) U.S. Cl. CPC H01L 21/67155; H02J 7/0063

(57) ABSTRACT

Methods and apparatus for commissioning a semiconductor processing tool include connecting a mobile facilities cart to a semiconductor processing tool; supplying facilities from the mobile facilities cart to the semiconductor processing tool; and operating the semiconductor processing tool using facilities supplied by the connected mobile facilities cart.

### CROSS-REFERENCE TO RELATED APPLICATIONS

This application claims benefit of U.S. provisional patent application Ser. No. 63/469,658, filed May 30, 2023, which is herein incorporated by reference in its entirety.

### FIELD

Embodiments of the present disclosure generally relate to commissioning of industrial equipment, and more specifically to commissioning of semiconductor processing tools.

### BACKGROUND

Semiconductor processing tools used in semiconductor processing are often brought online or otherwise commissioned onsite at a semiconductor processing site. For some semiconductor processing tools, the commissioning may take place in multiple stages or tiers (e.g., three tiers) before production qualification may even begin. Commissioning may include an initial tier 0, which may include initial placement of the semiconductor processing tool at a final location at a semiconductor processing site. Tier 1 may include a functional check and calibration of the semiconductor processing tool to ensure the tool is functioning correctly and is calibrated.

To perform tier 1 commissioning, for example, a semiconductor processing tool may be connected to one or more facilities of the semiconductor processing site. Examples of facilities may include at least one of power, compressed air (e.g., CDA), and vacuum. In some circumstances, such as during the construction or expansion of a semiconductor processing site, a semiconductor processing tool may be delivered to a semiconductor processing site before some or all of the facilities are available for the semiconductor processing tools. While the facilities remain unavailable, the semiconductor processing tool cannot be used, causing a delay in commissioning the semiconductor processing tool. A delay in any tier of commissioning may delay use of the semiconductor processing tool for production use.

Thus, the inventors propose methods, systems, and apparatus that mitigate the delays in commissioning and qualification of semiconductor processing tools caused by lack of site facilities.

### SUMMARY

Methods, system, and apparatus for commissioning a semiconductor tool are provided herein. The methods, systems, and apparatus can be used to commission a semiconductor processing tool even if the semiconductor processing tool is not connected to site facilities, such as power, compressed air (e.g., compressed dry air (CDA)), and vacuum. The methods, systems, and apparatus in accordance with embodiments of the present disclosure may provide some facilities to a semiconductor processing tool from a self-contained mobile platform such as a cart to allow the tool to be commissioned even while the tool is not connected to site facilities. Thus, the methods, systems, and apparatus in accordance with embodiments of the disclosure can mitigate commissioning delays caused by lack of facilities connections to tools.

In some embodiments, a method for commissioning a semiconductor processing tool includes connecting a mobile facilities cart to a semiconductor processing tool; supplying facilities from the mobile facilities cart to the semiconductor processing tool; and operating the semiconductor processing tool using facilities supplied by the connected mobile facilities cart.

In some embodiments, an apparatus for commissioning a semiconductor processing tool includes at least one battery pack configured to supply electrical power to the semiconductor processing tool via a power port; a compressor powered by the at least one battery pack, the compressor configured to supply compressed air to the semiconductor processing tool via a compressed air port; a vacuum pump powered by the at least one battery pack, the vacuum pump configured to supply vacuum to the semiconductor processing tool via a vacuum port; and a housing supporting the battery pack, the compressor, and the vacuum pump.

In some embodiments, a system for commissioning a semiconductor processing tool comprises a facilities cart comprising: a battery pack configured to supply electrical power to the semiconductor processing tool via a power port; a compressor powered by the battery pack, the compressor configured to supply compressed air to the semiconductor processing tool via a compressed air port; a vacuum pump powered by the battery pack, the vacuum pump configured to supply vacuum to the semiconductor processing tool via a vacuum port. The system may include a battery cart connected to the facilities cart. The battery cart may include a battery pack configured to supply electrical power to the facilities cart.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A shows a system for commissioning a semiconductor processing tool in accordance with some embodiments of the present disclosure.

FIG. 1B shows the facilities cart of FIG. 1A connected to mains power in accordance with some embodiments of the present disclosure.

FIG. 2 shows a method for commissioning a semiconductor processing tool in accordance with some embodiments of the present disclosure.

FIG. 3 shows details of a facilities cart in accordance with some embodiments of the present disclosure.

FIG. 4 shows an electrical schematic of a facilities cart in accordance with some embodiments of the present disclosure.

FIGS. 5A-5C show removal and installation of a battery pack from a facilities cart in accordance with some embodiments of the present disclosure.

FIG. 6 is a system in accordance with some embodiments of the present disclosure.

FIG. 7 is a system in accordance with some embodiments of the present disclosure.

FIG. 8 shows tests that can be completed using facilities supplied by a facilities cart in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method, system, and apparatus for commissioning a semiconductor processing tool are provided herein.

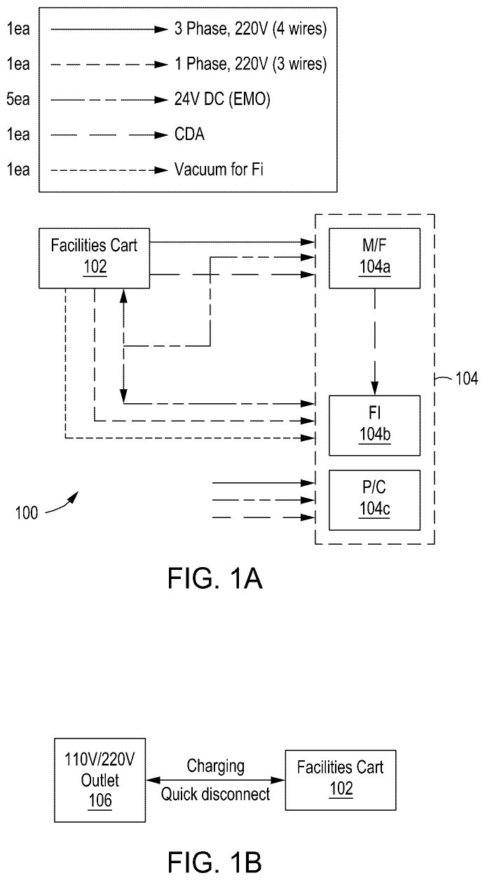

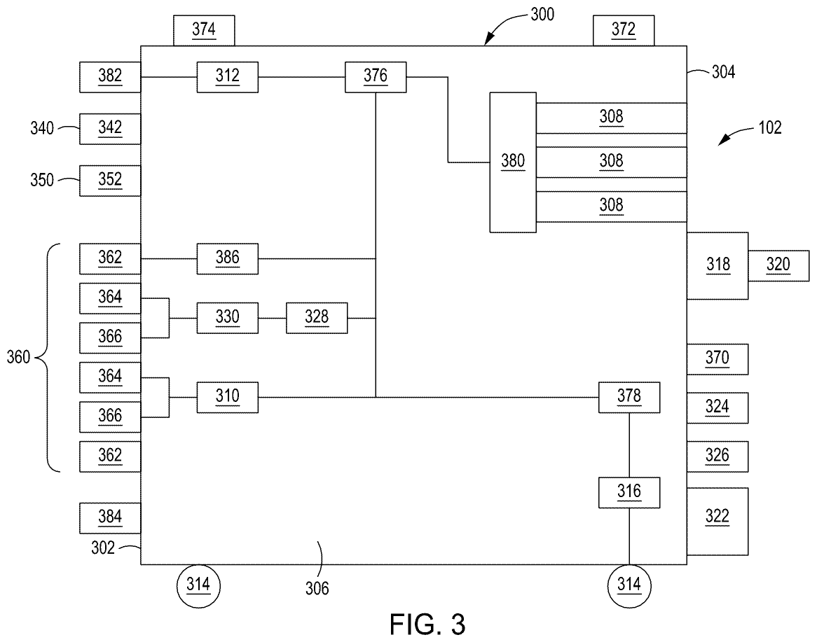

FIG. 1A shows a system 100 for commissioning a semiconductor processing tool 104 in accordance with some embodiments of the present disclosure. In some embodiments, and a shown in FIG. 1, the system 100 may include a facilities cart 102 and a semiconductor processing tool 104 that is operatively connected to the facilities cart 102. In some embodiments, and as shown in greater detail in FIG. 3, the facilities cart 102 may include one or more battery packs 308 that may be recharged by connecting the facilities cart 102 to a mains power supply 106, such as a 110V/220V electrical outlet as shown in FIG. 1B. In some embodiments, a quick disconnect connector (e.g., an electrical plug) may be used as an input power connector or power port 382 (FIG. 3) to connect the facilities cart 102 to the mains power supply 106 for charging the one or more battery packs 308.

In some embodiments, and as shown in FIG. 1A, the facilities cart 102 may be a self-contained cart that can supply one or more facilities to the semiconductor processing tool 104. In some embodiments, the facilities cart 102 may provide at least one of electrical power, compressed air (e.g., compressed dry air CDA), and vacuum. In some embodiments, the facilities cart may provide other or different facilities than electrical power, compressed air (e.g., CDA), and vacuum. In some embodiments, and as shown in FIG. 1A, the facilities cart 102 may include three-phase 220V power (e.g., one outlet), one-phase 220V power (e.g., one outlet), 24V DC power (e.g., 5 outlets), compressed air (e.g., one CDA connection), and vacuum (e.g., one connection).

In some embodiments, one or more electrical or fluid connections may be made between the facilities cart 102 and the semiconductor processing tool 104. In some embodiments, electrical connections may be made with cables or wires having at least one quick disconnect connector to connect to a corresponding quick disconnect on at least one of the facilities cart 102 or semiconductor processing tool 104. Also, in some embodiments, fluid connections (e.g., CDA or vacuum connections) may be made with hoses having at least one quick disconnect connector to a corresponding quick disconnect on at least one of the facilities cart 102 or semiconductor processing tool 104.

In some embodiments, and as shown in FIG. 1A, the semiconductor processing tool 104 may include one or more modules that may be connected to the facilities cart 102. In some examples, and a shown in FIG. 1A, the semiconductor processing tool 104 includes a mainframe (M/F) module 104a, a factory interface (FI) module 104b, and a process chamber (P/C) module 104c. In some embodiments, and as shown in FIG. 1A, the M/F module 104a may be connected to three phase electrical power, 24V DC electrical power, and compressed air (e.g., CDA); the FI module 104b may be connected to 24V DC power, one-phase power, and vacuum; and the P/C module 104c may be connected to three-phase power, 24V DC power, and compressed air (e.g., CDA). In some embodiments, and as shown in FIG. 1A, the FI module 104b may be supplied with compressed air (e.g., CDA) indirectly from the M/F module 104a. In some embodiments, the P/C module 104c may be connected to at least one of three-phase power or one-phase power. In some embodiments, while connected to the facilities cart 102, one or more of the modules 104a-104c may be operated independently from the other modules.

In some embodiments, the 24V DC power provided may be used to provide power (e.g., a reference signal) to an emergency shutoff circuit of the semiconductor processing tool 104. In some embodiments, a disconnection or switched interrupt of the 24V DC power to an emergency shutoff circuit may initiate an emergency shutdown of the semiconductor processing tool 104.

In some embodiments, semiconductor processing tool 104 may be a cluster tool comprising at least one of a vacuum processing chamber or wafer transfer chamber. In some embodiments, the cluster tool may be configured to operate at less than 500 torr during normal processing operation, and the facilities cart 102 provides vacuum at greater than 500 torr to the cluster tool. In some embodiments, the facilities provided by the facilities cart 102 to the semiconductor processing tool 104 include all of electrical power, compressed air (e.g., CDA), and vacuum.

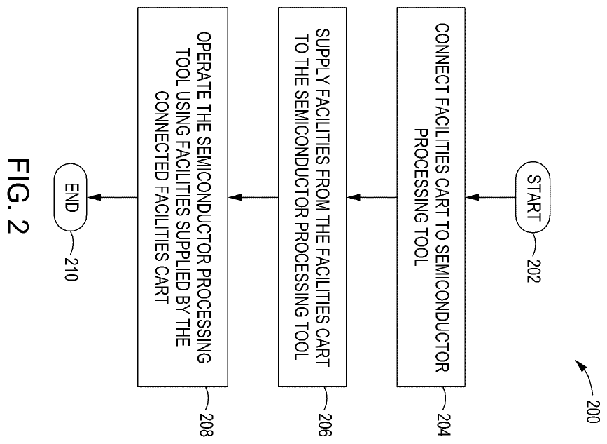

FIG. 2 is a method 200 for commissioning a semiconductor processing tool in accordance with some embodiments of the present disclosure. In some embodiments, at start 202, the method 200 may include providing a facilities cart (e.g., facilities cart 102) in accordance with embodiments of the disclosure. At block 204, the method 200 may include connecting the facilities cart to the semiconductor processing tool (e.g., semiconductor processing tool 104). At block 206, the method 200 may include supplying facilities from the facilities cart to the semiconductor processing tool. At block 208, the method 200 may include operating the semiconductor processing tool using facilities supplied by the connected facilities cart. In some embodiments, operating the semiconductor processing tool may include at least one of running a test or performing a calibration on the semiconductor processing tool. The method 200 may end at block 210 at the end of operating the semiconductor processing tool, after which the semiconductor processing tool may be disconnected from the facilities cart.

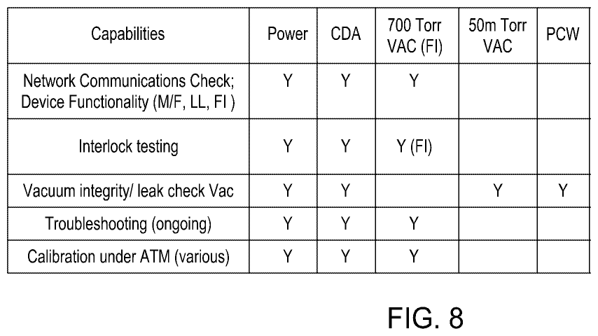

FIG. 8 shows tests that can be completed using facilities supplied by the facilities cart 102 in accordance with some embodiments of the present disclosure. In some embodiments, the facilities cart 102 may be used to perform a communications (e.g., network) check of the semiconductor processing tool 104 using power, compressed air (e.g., CDA), and vacuum supplied from the facilities cart 102 to the semiconductor processing tool 104. In some embodiments, a communications check may include checking communication of or between the M/F module 104a, the FI module 104b, the P/C module 104c, and other connected devices such as a computer system and peripherals. In some embodiments, a communications check may include checking device functionality of the semiconductor processing tool 104. In some embodiments, the facilities cart 102 may be used to perform interlock testing of the semiconductor processing tool 104 using power, compressed air (e.g., CDA), and vacuum supplied from the facilities cart 102 to the semiconductor processing tool 104. In some embodiments, the facilities cart 102 may be used to perform a vacuum integrity/leak check testing of the semiconductor processing tool 104 using power and compressed air (e.g., CDA) supplied from the facilities cart 102 to the semiconductor processing tool 104. In some embodiments, the facilities cart 102 may be used to perform troubleshooting of the semiconductor processing tool 104 using power, compressed air (e.g., CDA), and vacuum supplied from the facilities cart 102 to the semiconductor processing tool 104. In some embodiments, the facilities cart 102 may be used to perform calibration (e.g., robot calibration and alignment) testing of the semiconductor processing tool 104 using power, compressed air (e.g., CDA), and vacuum supplied from the facilities cart 102 to the semiconductor processing tool 104. In some embodiments, compressed air (e.g., CDA) may be used for gate and slit valve operations during robot calibrations. In some embodiments, vacuum may be used for ATM robot calibration and alignment in the FI module 104b. In some embodiments, and as shown in FIG. 3, the facilities cart 102 may include a housing 300 having a front side 302, a rear side 304, and left and right sides 306. In some embodiments, the facilities cart 102 may have a relatively compact footprint of about 30 inches wide and 45 inches long. In some embodiments, and as shown in FIG. 3, the facilities cart 102 may include one or more battery packs 308. In some embodiments, and as shown in FIG. 3, multiple battery packs 308 may be stacked and stored in a rack and connected to a bus bar 380. In some embodiments, the rear side 304 may be opened to provide access for installation and removal of one or more battery packs 308. In some embodiments, each battery pack 308 may be independently installed and removed for serviceability.

In some embodiments, and as shown in FIG. 3, the facilities cart 102 may include a dry (e.g., vacuum) pump 310. The vacuum pump 310 may be operated to supply vacuum for the semiconductor processing tool 104. In some embodiments, the vacuum pump 310 may provide a vacuum of at least 700 Torr. In some embodiments, and as shown in FIG. 3, the facilities cart 102 may include a compressor 328 and a storage tank 330 configured to supply compressed air (e.g., CDA) to the semiconductor processing tool.

In some embodiments, the facilities cart may be mobile. In some embodiment, and as shown in FIG. 3, the facilities cart 102 may have wheels 314 to permit the facilities cart 102 to move, i.e., forward and backward. In some embodiments, and as shown in FIG. 3, the facilities cart 102 may include a motor 316 (e.g., an accelerator motor) configured to drive the wheels 314 using power supplied by the battery packs 308. The motor 316 may be an AC 220V three-phase motor connected to a gearbox, which may have a 30:1 gear ratio. In some embodiments, the motor 316 and wheels 314 may be configured to move the facilities cart 102 at a speed of up to about 800 mm/second.

In some embodiments, and as shown in detail in FIG. 3, the facilities cart 102 may have a handle 318 to steer the facilities cart 102. In some embodiments, the handle 318 may be located on the rear side 304. In some embodiments, and as shown in FIG. 3, the facilities cart may include a throttle switch 320 on or near the handle 318 to control the motor 316 for driving the wheels 314. In some embodiments, and as shown in FIG. 3, the facilities cart 102 may include a cable and earthquake bracket basket 322. In some embodiments, and as shown in FIG. 3, the facilities cart 102 may include one or more cooling fans 324 that may provide cooling for one or more components of the facilities cart 102.

In some embodiments, and as shown in FIG. 3, the facilities cart may include a transformer 312 and an input power connector or power port 382 for connecting a battery charging cable to the facilities cart 102. Also, the facilities cart 102 may include an inverter 376 connected to the transformer 312, a motor inverter 378 connected to the inverter 376, and a ground connector 384 for connecting the facilities cart 102 to ground. The motor 316 may be connected to the motor inverter 378. The inverter 376 may be connected to the bus bar 380. In some embodiments, and as shown in FIG. 3, the facilities cart 102 may include a digital phase converter 386 connected to the inverter 376.

In some embodiments, the facilities cart 102 may include a battery and inverter remote monitor (battery management system, (BMS)) 326 configured for remote monitoring the health of the battery packs 108.

In some embodiments, and as shown in FIG. 3, the facilities cart 102 may include at least one of an electric breaker panel 340, a switch panel 350, or a facilities connection panel 360. The electric breaker panel 340 may include one or more circuit breakers 342 to protect at least one circuit between the facilities cart 102 and the semiconductor processing tool 104. In some embodiments, a circuit breaker 342 may be provided to protect at least one of the MF module 104a, the FI module 104b, and the P/C module 104c of the semiconductor processing tool 104.

In some embodiments, and as shown in FIG. 3, the switch panel 350 may include one or more switches 352 to control power to one or more components of the facilities cart 102.

In some embodiments, the facilities connection panel 360 may include at least one electrical connector or port 362 or a fluid connector or port 364 for routing at least one of the facilities provided by the facilities cart 102. In some embodiments, at least one of electrical connector or port 362 or fluid connector or port 364 may be a quick disconnect connector. In some embodiments, at least one electrical connector or port 362 may be a power port. In some embodiments, and as shown in FIG. 3, one or more indicators 366, such as a gauge, may be present to indicate pressure at a corresponding fluid connector or port 364. In some embodiments, one or more fluid connector or port 364 may be a compressed air (e.g., CDA) connector or port. In some embodiments, one or more fluid connector or port 364 may be a vacuum fluid connector or port.

In some embodiments, and shown in FIG. 3, the facilities cart 102 may include an emergency shutoff switch 370 connected to an emergency shutdown circuit to shut down the facilities cart 102 and the semiconductor processing tool 104 if connected to the facilities cart 102. In some embodiments, and as shown in FIG. 3, the facilities cart 102 may include a warning light 372, which may be illuminated to warn personnel that the facilities cart 102 is in motion. In some embodiments, and as shown in FIG. 3, the facilities cart 102 may include a signal tower or status light 374 that may be illuminated in various colors (e.g., red, yellow, green) to indicate a corresponding status of the facilities cart 102.

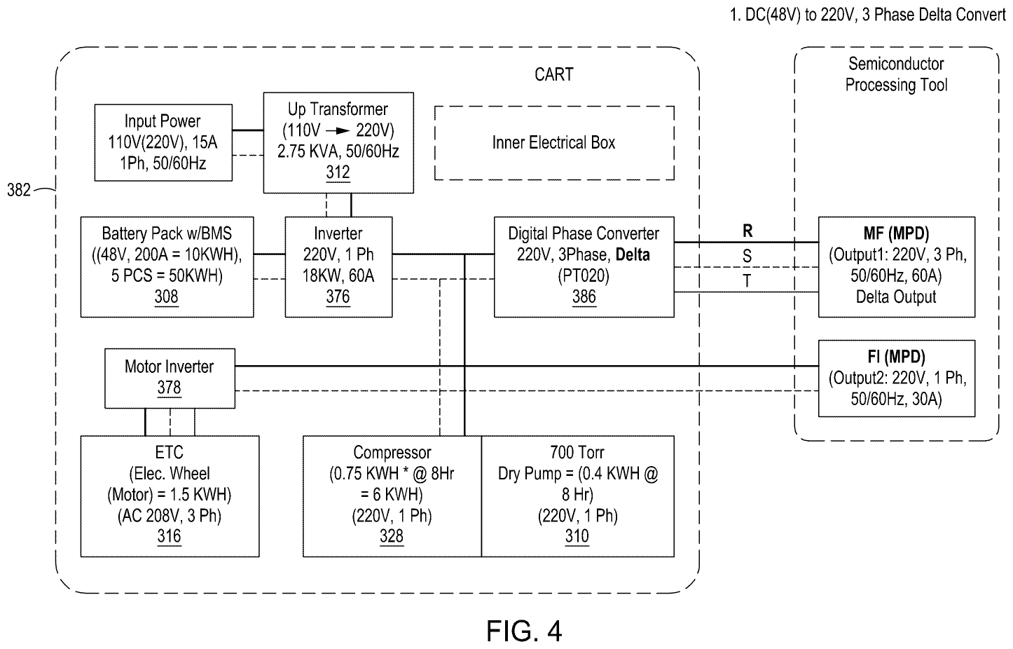

FIG. 4 is a schematic diagram showing electrical connections between components of the facilities cart 102 shown in FIG. 3 in accordance with embodiments of the present disclosure. In some embodiments, and as shown in FIG. 4, the input power connector or power port 382 is connected to the transformer 312. In some embodiments, input power connector or power port 382 is configured for receiving mains power (e.g., 110V or 220V, 15 A, 1 phase, 50/60 Hz). The transformer 312 may be configured to raise the mains voltage (e.g., 110V) to a higher voltage (e.g., 220V). The inverter 376 may be connected to the transformer 312 and may be configured (when the facilities cart 102 is connected to mains power) to receive and transfer the higher voltage mains power to the one or more battery packs 308 for charging the battery packs 308. In some embodiments, the inverter 376 may be a 220V, 1 phase 18 KW, 60 A inverter.

Also, the inverter 376 may be configured, when the facilities cart 102 is connected to the semiconductor processing tool 104, to invert power from the battery packs 308 and provide power to one or more electrically powered components housed in the facilities cart 102. For example, in some embodiments, and as described above, the facilities cart 102 may include the digital phase converter 386, the compressor 328, the vacuum pump 310, and the motor inverter 378 connected to the inverter 376. The inverter 376 may be configured to supply power to at least one of the digital phase converter 386, the compressor 328, the vacuum pump 310, and the motor inverter 378. In some embodiments, the digital phase converter 386 may be a 220V, three-phase delta digital phase converter configured to supply three phase electrical power to the semiconductor processing tool 104. In some embodiments, the compressor 328 is a 220V, one phase compressor that may be rated at 6 kilowatt-hours. In some embodiments, the vacuum pump 310 may be a 220V, one phase vacuum pump that may be rated at 0.4 kilowatt-hours. In some embodiments, the motor inverter 378 may be connected to the motor 316, which may operate on 208 VAC, three phase electrical power and may be rated for 1.5 kilowatt-hours.

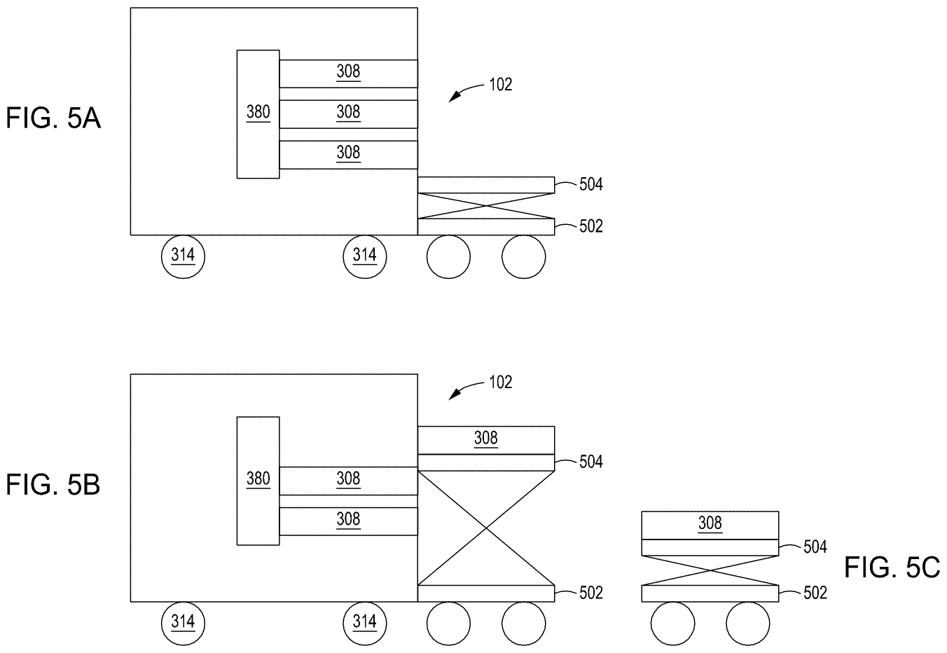

In some embodiments, a battery pack 308 can be removed and reinstalled from the facilities cart 102 using a lift cart. FIG. 5A shows the rear panel 3040 of the facilities cart 102 removed to expose the battery packs 308. In FIG. 5A, a lift cart 502 is moved into position adjacent to the rear side of the battery packs 308. The lift cart 502 may have a loading platform 504 and a mechanism to raise and lower the loading platform 504. In some embodiments, and as shown in FIG. 5B, the lift cart 502 may have a scissor lift 506 to raise the loading platform 504 into a position below a respective battery pack 308 to be removed. In some embodiments, and as shown in FIG. 5B, the loading platform may have rollers to allow the battery pack 308 to roll easily onto and off the loading platform 504. In some embodiments, the loading platform 504 may be raised to the position below a bottom of the battery pack 308 so that the battery pack 308 may be disconnected from the facilities cart and slid onto the loading platform 504. In some embodiments, and as shown in FIG. 5C, the battery pack 308 and the loading platform 504 may be lowered together for transporting the battery pack 308.

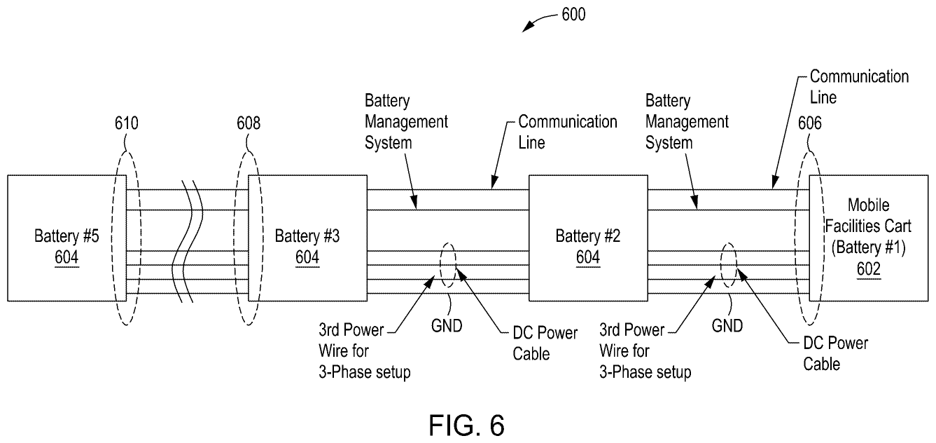

FIG. 6 shows an embodiment of a system 600 in accordance with the present disclosure. The system 600 includes a facilities cart 602 and one or more battery carts 604 coupled to the facilities cart 602. The additional battery carts 604 may expand the battery capacity of the facilities cart 602 to allow for extended run time of a semiconductor processing tool connected to the facilities cart 602. The facilities cart of the system 600 may be configured similar to the facilities cart 102 described above with reference to FIGS. 3 and 4 with the following exceptions. In some embodiments, and as shown in FIG. 6, the facilities cart 602 may include input connections 606 that include at least one of a communication line connection, a battery management system line connection, a power connection (AC or DC), and a ground connection.

In some embodiments, each battery cart 604 may be configured similar to the facilities cart 102 described above with reference to FIGS. 3 and 4 with the following exceptions. The battery carts 604 shown in FIG. 6 may have one or more battery packs 308, but may omit the compressor 328, the vacuum pump 310, the motor inverter 378, and the motor 316. In some embodiments, a battery cart 604 may have input connections (power and communication connections) 608 and output connections (power and communication connections) 610 to other battery carts 604 and/or the facilities cart 602.

In some embodiments, and as shown in FIG. 6, the output connections 610 of each battery cart 604 are connected to the input connections 608 of another battery cart 604 and/or the input connections 606 of the facilities cart 602 using a communication line, a battery management system line, a DC power cable, and a ground line. In some embodiments, the battery management system line is connected to the battery management system (e.g., battery management system 326) of the facilities cart 602 so that the battery packs in the battery carts 604 may be monitored and managed like the battery packs housed in the facilities cart 602. In some embodiments, the DC power connection is connected to the inverter (e.g., inverter 376) of the facilities cart. In some embodiments, the signal line may be connected to an emergency shutoff circuit and the emergency shutoff switch (e.g., emergency shutoff switch 370) of the facilities cart. In some embodiments, each battery cart 604 may have an emergency shutoff switch connected to the signal line.

In some embodiments, the battery carts 604 may be physically connected to each other and the facilities 602 cart by a mechanical connection, such as a tow bar or linkage so that the one or more battery carts 604 may be moved (e.g., wheeled) with the facilities cart without putting strain on the DC power cable, ground line, battery management system line, and communication line.

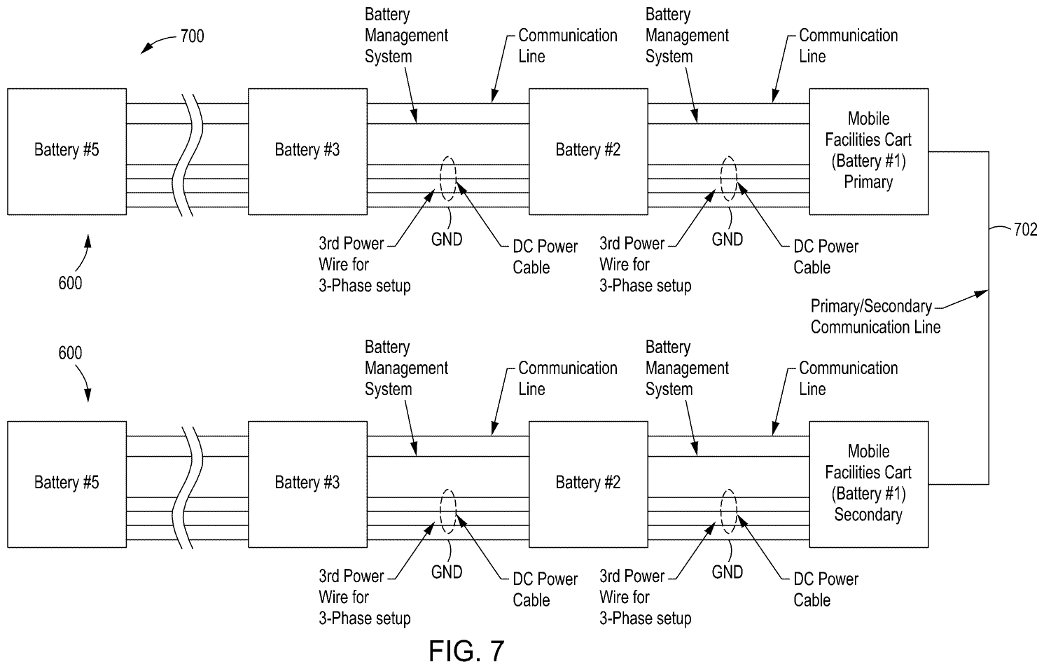

FIG. 7 shows another embodiment of a system 700 in accordance with the present disclosure. In some embodiments, the system 700 may combine two or more of the systems 600 shown in FIG. 6 with a communication line 702. In some embodiments, the communication line 702 may connect to the emergency management circuit of each system 600 and of the semiconductor processing tool 104. In some embodiments, the systems 600 may be connected electrically in parallel with a semiconductor processing tool 104 to provide redundancy in the event that one system 600 fails.

While the foregoing is directed to embodiments of the present disclosure, other and further embodiments of the disclosure may be devised without departing from the basic scope thereof.

1. A method for commissioning a semiconductor processing tool, the method comprising:
connecting a mobile facilities cart to a semiconductor processing tool;
supplying facilities from the mobile facilities cart to the semiconductor processing tool; and
operating the semiconductor processing tool using facilities supplied by the connected mobile facilities cart.

2. The method of claim 1, wherein operating the semiconductor processing tool includes at least one of running a test or performing a calibration on the semiconductor processing tool.

3. The method of claim 2, wherein the test includes at least one of a network communications check; an interlock test; a vacuum integrity/leak check; troubleshooting; or calibration.

4. The method of claim 2, wherein the semiconductor processing tool is a cluster tool comprising at least one of a vacuum processing chamber or wafer transfer chamber the cluster tool configured to operate at less than 500 torr during normal processing operation, and the mobile facilities cart provides vacuum at greater than 500 torr to the cluster tool.

5. The method of claim 1, wherein the facilities provided by the mobile facilities cart to the semiconductor processing tool include all of electrical power, compressed air, and vacuum.

6. The method of claim 1, wherein the facilities provided by the mobile facilities cart to the semiconductor processing tool include at least one of electrical power, compressed air, or vacuum.

7. The method of claim 1, wherein the mobile facilities cart is connected to at least one battery cart.

8. The method of claim 1, further comprising connecting another mobile facilities cart to the semiconductor processing tool.

9. An apparatus for commissioning a semiconductor processing tool, the apparatus comprising:
at least one battery pack configured to supply electrical power to the semiconductor processing tool via a power port;
a compressor powered by the at least one battery pack, the compressor configured to supply compressed air to the semiconductor processing tool via a compressed air port;
a vacuum pump powered by the at least one battery pack, the vacuum pump configured to supply vacuum to the semiconductor processing tool via a vacuum port; and
a housing supporting the battery pack, the compressor, and the vacuum pump.

10. The apparatus of claim 9, further comprising wheels supporting the housing.

11. The apparatus of claim 10, further comprising a motor powered by the at least one battery pack, the motor configured to drive the wheels.

12. The apparatus of claim 9, further comprising:
a compressed air port coupled to the compressor;
a vacuum port coupled to the vacuum pump; and
a power port coupled to the battery pack.

13. The apparatus of claim 12, wherein at least one of the compressed air port, the vacuum port, or the power port is a quick disconnect connector.

14. The apparatus of claim 9, wherein the vacuum pump is configured to provide vacuum at greater than 500 torr.

15. The apparatus of claim 9, further comprising a phase converter coupled to the at least one battery pack for converting the electrical power to three phase electrical power.

16. The apparatus of claim 9, further comprising at least one input connection for receiving electrical power from a battery cart.

17. A system for commissioning a semiconductor processing tool, the system comprising:
a facilities cart comprising:
a battery pack configured to supply electrical power to the semiconductor processing tool via a power port;
a compressor powered by the battery pack, the compressor configured to supply compressed air to the semiconductor processing tool via a compressed air port;
a vacuum pump powered by the battery pack, the vacuum pump configured to supply vacuum to the semiconductor processing tool via a vacuum port; and
a battery cart connected to the facilities cart, the battery cart comprising:
a battery pack configured to supply electrical power to the facilities cart.

18. The system of claim 17, wherein the battery cart is configured to provide at least one of AC or DC power to the facilities cart.

19. The system of claim 17, wherein the facilities cart includes a battery management system configured for monitoring the health of the battery pack of the facilities cart and the battery pack of the battery cart.

20. The system of claim 17, further comprising wheels supporting the facilities cart and wheels supporting the battery cart, wherein the facilities cart and the battery cart are connected to be wheeled together.
